(19) United States
(12) Patent Application Publication
(10) Pub. No.: US 2013/0168803 A1
(43) Pub. Date: Jul. 4, 2013

(54) Semiconductor-On-Insulator Devices and Associated Methods

(71) Applicants: Homayoon Haddad, Beaverton, OR (US); Leonard Forbes, Corvallis, OR (US)

(72) Inventors: Homayoon Haddad, Beaverton, OR (US); Leonard Forbes, Corvallis, OR (US)

(73) Assignee: SIONYX, INC., Beverly, MA (US)

(21) Appl. No.: 13/621,737

(22) Filed: Sep. 17, 2012

Related U.S. Application Data
(60) Provisional application No. 61/535,631, filed on Sep. 16, 2011.

(51) Int. Cl. H01L 21/50; H01L 29/16

(52) U.S. Cl. CPC H01L 21/50; H01L 29/16
USPC 257/507; 438/106; 257/506

(57) ABSTRACT

Semiconductor-on-insulator (SOI) devices and associated methods are provided. In one aspect, for example, a method for making a SOI device can include forming a device layer on a front side of a semiconductor layer, bonding a first substrate to the front side of the device layer, processing the semiconductor layer on a back side opposite the device layer to form a processed surface, and bonding a second substrate to the processed surface. In some aspects, the method can further include removing the first substrate from the front side to expose the device layer. In one aspect, forming the device layer can include forming optoelectronic circuitry at the front side of the semiconductor layer.

### PRIORITY DATA

This application claims the benefit of U.S. Provisional Patent Application Ser. No. 61/535,631, filed on Sep. 16, 2011, which is incorporated herein by reference.

### BACKGROUND

Silicon-on-insulator substrates for devices, circuits, imagers and sensors are traditionally made by any one of a number of commercial processes, including, for example, the “smart cut” process, the Separation by Implantation of Oxygen (SIMOX) process, and silicon grown by epitaxial techniques on sapphire (SOS). In all of the processes, however, damage is introduced into the silicon layers at the beginning of the processes.

For example, the smart cut process was commercialized by the French company SOITEC. The process uses ion implantation followed by controlled separation of the thin top layer of the sacrificial wafer to determine the thickness of the uppermost silicon layer. A sacrificial wafer is implanted with protons to introduce a buried defect layer that will later allow separation of a thin silicon topmost layer. A permanent carrier wafer having an oxide surface layer is bonded to the sacrificial layer at the side from which the thin silicon topmost layer will be taken. When the sacrificial layer is split at the defect layer, the thin silicon layer remains bonded to the oxide of the permanent carrier wafer. Additional processing steps are required to anneal out defects in the thin silicon layer and for surface preparation before devices, circuits, imagers or sensors can be fabricated using conventional silicon integrated circuit techniques.

In the SIMOX process, a buried SiO₂ layer is created within a substrate by oxygen ion beam implantation followed by high temperature annealing. As with the smart cut process, additional processing steps are required to anneal out defects in the thin silicon layer and for surface preparation before devices, circuits, imagers or sensors can be fabricated using conventional silicon integrated circuit techniques.

In a typical silicon-on-sapphire process (SOS), SOS is formed by epitaxial deposition of a thin layer of silicon onto a sapphire wafer at high temperatures. Due to the lattice mismatch between the crystalline silicon layer and crystalline sapphire substrate, significant defects can arise in the thin silicon layer. Additional processing steps are therefore required to anneal out these defects in the thin silicon layer and for surface preparation before devices, circuits, imagers or sensors can be fabricated using conventional silicon integrated circuit techniques.

Direct bonding and thinning is a process that can be used to form silicon-on-insulator layers via the bonding of two silicon wafers, at least one of which has an oxide layer. The front side of the top silicon wafer can be thinned to provide a silicon-on-insulator structure. Additionally, modern integrated circuit and imager technologies often require very thin layers of the order a few micrometers of silicon be left or remaining on the insulator, so a significant amount of backside grinding, polishing, and chemical etch are necessary to achieve such a thin layer.

### SUMMARY

The present disclosure provides semiconductor-on-insulator (SOI) devices and associated methods. In one aspect, for example, a method for making a semiconductor-on-insulator device is provided. Such a method can include forming a device layer on a front side of a semiconductor layer, bonding a first substrate to the front side of the device layer, processing the semiconductor layer on a backside opposite the device layer to form a processed surface, and bonding a second substrate to the processed surface. In some aspects, the method can further include removing the first substrate from the front side to expose the device layer. In one aspect, forming the device layer can include forming optoelectronic circuitry at the front side of the semiconductor layer. Non-limiting examples of optoelectronic circuitry can include CMOS circuitry, imaging devices, RF circuitry, photovoltaic circuitry, and the like, including combinations thereof. In a further aspect, the method can include forming backside circuitry at the processed surface prior to bonding the second substrate to the processed surface.

In another aspect, processing the semiconductor layer on the backside can further include thinning the semiconductor layer from the back side to expose the device layer. In yet another aspect, processing the semiconductor layer on the back side can further include implant conditions to reduce surface defects. In a further aspect, bonding the second substrate to the processed surface can further include oxide-oxide bonding the second substrate to the processed surface.

In another aspect, a SOI device is provided. Such a device can include a semiconductor layer having a device layer on a front side and a CMP processed surface opposite the front side, a first substrate oxide bonded to the device layer of the semiconductor layer, and a second substrate oxide bonded to the processed surface of the semiconductor layer. In one aspect, the device layer is substantially defect free. In another aspect, the semiconductor layer includes a silicon material. In yet another aspect, the silicon material is a single crystal silicon wafer. In a further aspect, the second substrate is an insulating substrate. In yet a further aspect, the second substrate is a sapphire layer. In another aspect, the second substrate is a permanent substrate.

### BRIEF DESCRIPTION OF THE DRAWINGS

For a fuller understanding of the nature and advantage of the present disclosure, reference is being made to the following detailed description of various embodiments and in connection with the accompanying drawings, in which:

FIG. 1 is a flow diagram of a method for making a SOI device in accordance with an aspect of the present disclosure.

FIG. 2a shows a cross sectional view of various steps in the manufacture of a SOI device in accordance with another aspect of the present disclosure.

FIG. 2b shows a cross sectional view of various steps in the manufacture of a SOI device in accordance with another aspect of the present disclosure.

FIG. 2c shows a cross sectional view of various steps in the manufacture of a SOI device in accordance with another aspect of the present disclosure.

FIG. 2d shows a cross sectional view of various steps in the manufacture of a SOI device in accordance with another aspect of the present disclosure.

FIG. 2e shows a cross sectional view of various steps in the manufacture of a SOI device in accordance with another aspect of the present disclosure.

FIG. 3a shows a cross sectional view of various steps in the manufacture of a SOI device in accordance with another aspect of the present disclosure.

FIG. 3b shows a cross sectional view of various steps in the manufacture of a SOI device in accordance with another aspect of the present disclosure.

FIG. 3c shows a cross sectional view of various steps in the manufacture of a SOI device in accordance with another aspect of the present disclosure.

FIG. 3d shows a cross sectional view of various steps in the manufacture of a SOI device in accordance with another aspect of the present disclosure.

FIG. 3e shows a cross sectional view of various steps in the manufacture of a SOI device in accordance with another aspect of the present disclosure.

FIG. 4 shows a SOI bonding technique in accordance with another aspect of the present disclosure.

FIG. 5 shows a SOI bonding technique in accordance with another aspect of the present disclosure.

### DETAILED DESCRIPTION

Before the present disclosure is described herein, it is to be understood that this disclosure is not limited to the particular structures, process steps, or materials disclosed herein, but is extended to equivalents thereof as would be recognized by those ordinarily skilled in the relevant arts. It should also be understood that terminology employed herein is used for the purpose of describing particular embodiments only and is not intended to be limiting.

### DEFINITIONS

The following terminology will be used in accordance with the definitions set forth below.

It should be noted that, as used in this specification and the appended claims, the singular forms “a,” and, “the” include plural referents unless the context clearly dictates otherwise. Thus, for example, reference to “a dopant” includes one or more of such dopants and reference to “the layer” includes reference to one or more of such layers.

As used herein, the term “defect free” refers to a material having no observable crystal lattice defects. Additionally, the term “substantially defect free” refers to a material that is at least about 95% free of crystal lattice defects.

As used herein, the terms “disordered surface” and “textured surface” can be used interchangeably, and refer to a surface having a topology with nano- to micron-sized surface variations formed by the irradiation of laser pulses or other texturing methods such as chemical etching as described herein. While the characteristics of such a surface can be variable depending on the materials and techniques employed, in one aspect such a surface can be several hundred nanometers thick and made up of nanocrystallites (e.g. from about 10 to about 50 nanometers) and nanopores. In another aspect, such a surface can include micron-sized structures (e.g. about 2 μm to about 60 μm). In yet another aspect, the surface can include nano-sized and/or micron-sized structures from about 5 nm and about 500 μm.

As used herein, the terms “surface modifying” and “surface modification” refer to the altering of a surface of a semiconductor material using a variety of surface modification techniques. Non-limiting examples of such techniques include plasma etching, reactive ion etching, porous silicon etching, lasing, chemical etching (e.g. anisotropic etching, isotropic etching), nanoimprinting, material deposition, selective epitaxial growth, and the like, including combinations thereof. In one specific aspect, surface modification can include processes using primarily laser radiation or laser radiation in combination with a dopant, whereby the laser radiation facilitates the incorporation of the dopant into a surface of the semiconductor material. Accordingly, in one aspect surface modification includes doping of a substrate such as a semiconductor material.

As used herein, the term “target region” refers to an area of a substrate that is intended to be doped or surface modified. The target region of the substrate can vary as the surface modifying process progresses. For example, after a first target region is doped or surface modified, a second target region may be selected on the same substrate.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result. For example, a composition that is “substantially free of” particles would either completely lack particles, or so nearly completely lack particles that the effect would be the same as if it completely lacked particles. In other words, a composition that is “substantially free of” an ingredient or element may still actually contain such item as long as there is no measurable effect thereof.

As used herein, the term “about” is used to provide flexibility to a numerical range endpoint by providing that a given value may be “a little above” or “a little below” the endpoint.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges such as from 1-3, from 2-4, and from 3-5, etc., as well as 1, 2, 3, 4, and 5, individually.

This same principle applies to ranges reciting only one numerical value as a minimum or a maximum. Furthermore, such an interpretation should apply regardless of the breadth of the range or the characteristics being described.

The Disclosure

Various benefits can be obtained from a semiconductor-on-insulator (SOI) substrate, including a low parasitic capacitance (providing increased speed), lower power consumption, and more isolation than bulk silicon in digital integrated circuits. In analog or high frequency RF integrated circuits, for example, thin SOI transistors have better linearity and more isolation than in bulk. Insulating substrates also enable the fabrication of high quality factor (Q) inductors, as there are no eddy currents induced in the substrate.

As another example, silicon-on-sapphire (SOS) devices and circuits are substantially immune to a single event upset in space borne applications caused by high energy particles. Epitaxial silicon films grown on sapphire are, as is describe above, under high compressive stress and thus yield devices with a large number of defects. The higher cost of conventional silicon on insulator wafers, combined with the fact that all generally have higher defect densities than conventional silicon wafers, have precluded wide acceptance to SOI technologies in spite of their many advantages.

The inventors, however, have developed techniques for producing devices, circuits, imagers, and sensors in defect-free or very low defect density thin SOI wafers. This can be accomplished by first forming the devices, circuits, imagers, sensors, and the like on a front side surface of an epitaxial semiconductor wafer, such as, for example, standard wafers used in conventional integrated circuit technology with very few defects. These wafers can be supported by a first or front side substrate while the backside is thinned. In some cases, additional processing can be performed on the backside. A second or backside substrate can then be bonded to the backside surface of the semiconductor wafer, and the first substrate can be released to expose the front side surface. In one aspect, all the backside thinning and processing steps, including bonding, can be performed at low temperatures. In this manner, the thin semiconductor (e.g. silicon) epitaxial layer on the semiconductor wafer is defect free and can be maintained defect free during all subsequent processing steps, as opposed to starting with a highly defected thin semiconductor layer and having to remove defects by further processing as in traditional (SOI) technologies.

Accordingly, defect free or substantially defect free semiconductor substrates, layers, devices, circuits, sensors, and the like, can be coupled to SOI substrates after the fabrication of these front side device layers. The resulting SOI wafer experiences low temperature processes after this point that will not introduce significant defects. Because such devices are formed on substantially defect free epitaxial semiconductor wafers, the final devices are also substantially defect free unlike devices made from most conventional SOI process techniques where the starting substrate has a high number of defects and efforts are made to anneal out and reduce or remove these defects before forming the device layer.

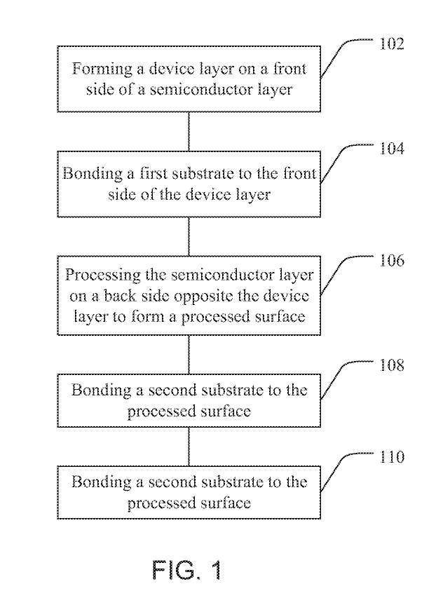

In one aspect, for example, a method for making a SOI device can include, as is shown in FIG. 1, forming a device layer on a front side of a semiconductor layer 102, bonding a first substrate to the front side of the device layer 104, processing the semiconductor layer on a back side opposite the device layer to form a processed surface 106, bonding a second substrate to the processed surface 108, and removing the first substrate from the front side to expose the device layer 110.

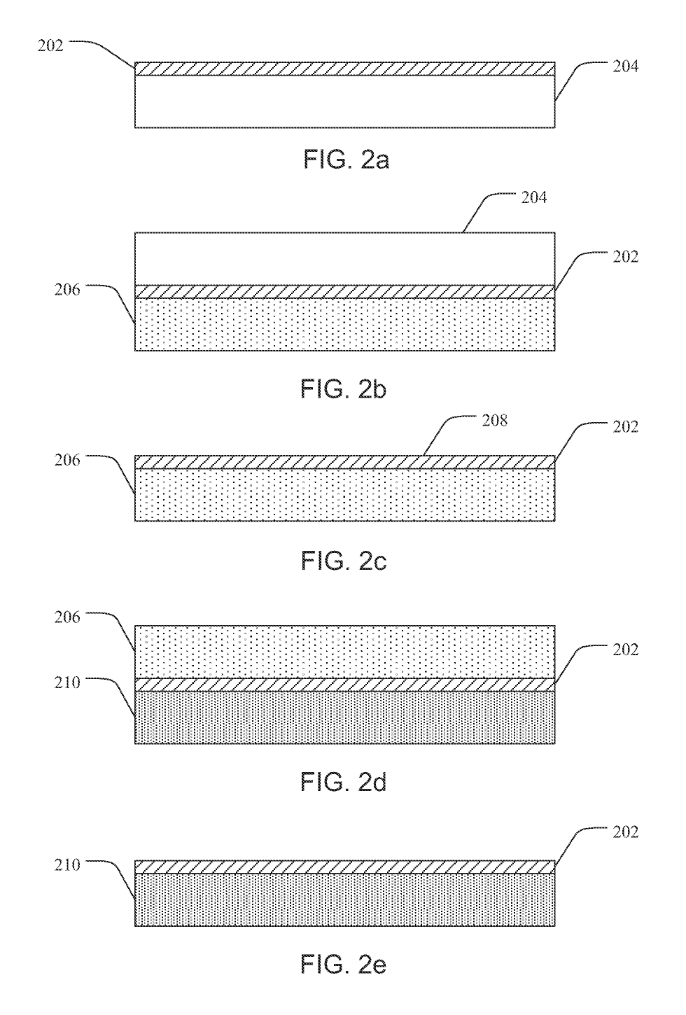

FIGS. 2a-e show various steps in the manufacture of a SOI device according to one aspect of the present disclosure. As is shown in FIG. 2a, for example, device layer 202 is formed on the front side of a semiconductor layer 204. The device layer 202 can include any form of device layer that can be incorporated into a SOI device, and any such device is considered to be within the present scope. In one aspect, for example, the device layer can include optoelectronic circuitry. While any type of optoelectronic circuitry is considered, non-limiting examples can include CMOS circuitry, imaging devices, RF circuitry, photovoltaic circuitry, and the like, including combinations thereof. It is also contemplated that non-optoelectronic device layer circuitry, either in addition to or instead of optoelectronic circuitry, is within the present scope. As such, the present methods and devices should not be limited to optoelectronics.

While the semiconductor layer can be made from a variety of materials, it can be beneficial for the semiconductor to be defect free or substantially defect free. Such a defect free semiconductor layer thus allows the formation of a defect free or substantially defect free device layer thereupon. Provided defects are not introduced into the device layer from additional processing steps, the device layer can be maintained in the original defect free state. As one example, in some aspects the SOI device is not heated to a temperature of greater than 450° C. following the formation of the device layer.

A variety of semiconductor materials are contemplated for use as the semiconductor layer of the devices and methods according to aspects of the present disclosure. As such, any semiconductor material that can be used in a SOI device is considered to be within the present scope. Non-limiting examples of such semiconductor materials can include group IV materials, compounds and alloys comprised of materials from groups II and VI, compounds and alloys comprised of materials from groups III and V, and combinations thereof. More specifically, exemplary group IV materials can include silicon, carbon (e.g. diamond), germanium, and combinations thereof. Various exemplary combinations of group IV materials can include silicon carbide (SiC) and silicon germanium (SiGe).

Exemplary combinations of group II-VI materials can include cadmium selenide (CdSe), cadmium sulfide (CdS), cadmium telluride (CdTe), zinc oxide (ZnO), zinc selenide (ZnSe), zinc sulfide (ZnS), zinc telluride (ZnTe), cadmium zinc telluride (CdZnTe, CZT), mercury cadmium telluride (HgCdTe), mercury zinc telluride (HgZnTe), mercury zinc selenide (HgZnSe), and combinations thereof.

Exemplary combinations of group III-V materials can include aluminum antimonide (AlSb), aluminum arsenide (AlAs), aluminum nitride (AlN), aluminum phosphide (AlP), boron nitride (BN), boron phosphide (BP), boron arsenide (BAs), gallium antimonide (GaSb), gallium arsenide (GaAs), gallium nitride (GaN), gallium phosphide (GaP), indium antimonide (InSb), indium arsenide (InAs), indium nitride (InN), indium phosphide (InP), aluminum gallium arsenide (AlGaAs, AlxGal-xAs), indium gallium arsenide (InGaAs, InxGal-xAs), indium gallium phosphide (InGaP), aluminum indium arsenide (AlInAs), aluminum indium antimonide (AlInSb), gallium arsenide nitride (GaAsN), gallium arsenide phosphide (GaAsP), aluminum gallium nitride (AlGaN), aluminum gallium phosphide (AlGaP), indium gallium nitride (InGaN), indium arsenide antimonide (InAsSb), indium gallium antimonide (InGaSb), aluminum gallium indium phosphide (AlGaInP), aluminum gallium arsenide phosphide (AlGaAsP), indium gallium arsenide phosphide (InGaAsP), aluminum indium arsenide phosphide (AIInAsP), aluminum gallium arsenide nitride (AlGaAsN), indium gallium arsenide nitride (InGaAsN), indium aluminum arsenide nitride (InAlAsN), gallium arsenide antimonide nitride (GaAsSbN), gallium indium nitride arsenide antimonide (GaInNAsSb), gallium indium arsenide antimonide phosphide (GaInAsSbP), and combinations thereof.

In one specific aspect, the semiconductor layer can include silicon. In another specific aspect, the semiconductor layer can be a silicon wafer. The silicon wafer/material can be monocrystalline, multicrystalline, microcrystalline, amorphous, and the like. In one specific aspect, the silicon material can be a single crystal silicon wafer.

Turning to FIG. 2b, a first substrate 206 (or front side substrate) can be bonded to the device layer 202. Note that in FIG. 2b, the device has been flipped or rotated 180°. The first substrate can include a variety of materials. Because in most aspects the first substrate 206 is a temporary substrate to be removed at a later processing step, the material can be chosen based on its usefulness as a temporary substrate. It can also be beneficial for the first substrate to be capable of adequately holding the device layer during processing of the semiconductor material and yet be capable of easy removal. Non-limiting examples of potential first substrate materials can include glass, ceramics, semiconductors, and the like, including combinations thereof.

Various bonding techniques are contemplated, and any such bonding technique useful in making a SOI device is considered to be within the present scope. In one aspect, for example, the bonding technique can be a low temperature technique (e.g. below 450° C.). In another aspect, the bonding can occur at room temperature or in other words, the bonding does not require a heat source. In another aspect, the semiconductor layer and the first substrate can be bonded at room temperature and a thermal treatment can be applied to consolidate the bonding interface, provided the thermal treatment is performed at a temperature that does not exceed 450° C. The parameters of the consolidation annealing can be controlled to provide a bonding energy high enough for the heterostructure to withstand post-bonding conventional CMOS process steps. In one specific aspect, the bonding technique can include various oxide wafer bonding methods.

Some bonding processes can achieve a bond strength of at least 1 J/m² at room temperature. For even higher bond strengths, a bake cycle at 100°-300° C. can be utilized. Some of these oxide-oxide bonding process have been described in U.S. Pat. No. 7,871,898 and U.S. Pat. No. 5,843,832, which are incorporated by reference in their entireties. One method of direct bonding a silicon wafer onto an insulated wafer in order to obtain a SOI device is similar to the bonding of two silicon wafers together, with the exception that before bonding a thin thermal oxide layer (e.g. about 1 micron) is grown on one of the wafers.

Turning to FIG. 2c, the semiconductor layer 204 (FIG. 2b) is at least partially removed (e.g. polished and thinned) to expose the backside of the device layer 202 or, in other words, to form a processed surface 208 at the backside of the device layer 202. Thus, the resulting structure is comprised of the first substrate 206 coupled to the thin device layer 202. At this point, any necessary or beneficial backside processing can be performed on the device layer 202. Such beneficial backside processing can include, without limitation, texturing the back surface of device layer 202. Thus, in some aspects the exposed surface of the device layer 202 can be textured, while in other aspects the buried surface of the device layer 202 can be textured at a point in the manufacturing process when that surface is available for processing. In another specific aspect, processing the semiconductor layer on the backside can include implant and/or laser anneal conditions to reduce surface defects. It is also contemplated that backside circuitry can be formed at the backside surface of the device layer 202 prior to bonding the second substrate to the processed surface 208.

Any technique useful for removing the semiconductor layer is considered to be within the present scope, provided that the processing temperature does not exceed 450° C. Non-limiting examples can include ion implantation/separation processes, laser ablation, laser splitting, CMP processing, dry etching, wet etching and the like, including combinations thereof. In one specific aspect, the semiconductor layer is removed by CMP techniques to expose the device layer 202.

Following removal or thinning of the semiconductor layer 204, a second substrate 210 is bonded to the backside of the device layer 202, as is shown in FIG. 2d. Note that in FIG. 2d, the device has been flipped so that the first substrate 206 is directed upward. Any bonding technique can be utilized to bond the second substrate 210 to the device layer 202, as was described for the bonding of the first substrate 206 to the device layer 202 (FIG. 2b).

The second substrate can include a variety of materials, depending on the desired design and subsequent properties of the device. In some aspects, the second substrate 210 is a permanent substrate that will be incorporated into the finished device. As such, the material utilized for the second substrate can be selected to provide desired benefits. In one aspect, for example, the second substrate can be a substrate with insulating properties, or in other words, an insulating substrate. In another aspect, the second substrate can include sapphire, or can be a sapphire substrate. In another aspect, the second substrate can be an oxide material.

Turning to FIG. 2e, in some aspects the first substrate 206 (FIG. 2d) can be removed from the device layer 202 following bonding of the second substrate 210. Thus, the resulting SOI structure shown in FIG. 2e includes an insulating substrate (second substrate 210) bonded to the device layer 202 (or in some cases a remaining portion of the semiconductor layer 204). Because of the defect free formation of the device layer 202 on the semiconductor layer 204, and the subsequent low temperature processing of the SOI device, the device layer 202 remains defect free or substantially defect free in the final SOI substrate or SOI device. It should be noted that the scope of the present disclosure includes the SOI substrate shown in FIG. 2e, as well as the intermediate structures produced during the formation of the SOI substrate.

As has been described, at least a portion of the semiconductor device can include a textured region. Such a textured region can be applied to any of the materials of the device that can be beneficial. For example, at least a portion of either side of the device layer, or a remaining portion of either side of the semiconductor layer, can be textured. In other aspects, at least a portion of the second substrate can be textured.

The textured region can function to diffuse electromagnetic radiation, to redirect electromagnetic radiation, and to absorb electromagnetic radiation, thus increasing the quantum efficiency of the device. The textured region can include surface features to thus increase the effective absorption length of the semiconductor. Such surface features can be micron-sized and/or nano-sized, and can be any shape or configurations. Non-limiting examples of such shapes and configurations include cones, pillars, pyramids, micolenses, quantum dots, inverted features, gratings, protrusions, and the like, including combinations thereof. Additionally, factors such as manipulating the feature sizes, dimensions, material type, dopant profiles, texture location, etc. can allow the diffusing region to be tunable for a specific wavelength or wavelength range. Thus in one aspect, tuning the device can allow specific wavelengths or ranges of wavelengths to be absorbed.

Textured regions according to aspects of the present disclosure can also allow an optoelectronic device to experience multiple passes of incident electromagnetic radiation within the device, particularly at longer wavelengths (i.e. infrared). Such internal reflection increases the effective absorption length to be greater than the thickness of the semiconductor. This increase in absorption length increases the quantum efficiency of the device, leading to an improved signal to noise ratio.

The textured region can be formed by various techniques, including plasma etching, reactive ion etching, porous silicon etching, lasing, chemical etching (e.g. anisotropic etching, isotropic etching), nanoimprinting, material deposition, selective epitaxial growth, and the like. One effective method of producing a textured region is through laser processing. Such laser processing allows discrete locations of the passivation region or other substrate to be textured. A variety of techniques of laser processing to form a textured region are contemplated, and any technique capable of forming such a region should be considered to be within the present scope. Laser treatment or processing can allow, among other things, enhanced absorption properties and thus increased electromagnetic radiation focusing and detection. The laser treated region can be associated with the surface nearest the impinging electromagnetic radiation or, in some cases, the laser treated surface can be associated with a surface opposite in relation to impinging electromagnetic radiation, thereby allowing the radiation to pass through the semiconductor before it hits the laser treated region.

In one aspect, for example, a target region of a semiconductor material can be irradiated with laser radiation to form a textured region. Examples of such processing have been described in further detail in U.S. Pat. Nos. 7,057,256, 7,354,792 and 7,442,629, which are incorporated herein by reference in their entireties. Briefly, a surface of a substrate material is irradiated with laser radiation to form a textured or surface modified region.

The type of laser radiation used to surface modify a material can vary depending on the material and the intended modification. Any laser radiation known in the art can be used with the devices and methods of the present disclosure. There are a number of laser characteristics, however, that can affect the surface modification process and/or the resulting product including, but not limited to the wavelength of the laser radiation, pulse width, pulse fluence, pulse frequency, polarization, laser propagation direction relative to the semiconductor material, etc. In one aspect, a laser can be configured to provide pulsatile lasing of a material. A short-pulsed laser is one capable of producing femtosecond, picosecond and/or nanosecond pulse durations. Laser pulses can have a central wavelength in a range of about from about 10 nm to about 8 μm, and more specifically from about 200 nm to about 1200 nm. The pulse width of the laser radiation can be in a range of from about tens of femtoseconds to about hundreds of nanoseconds. In one aspect, laser pulse widths can be in the range of from about 50 femtoseconds to about 50 picoseconds. In another aspect, laser pulse widths can be in the range of from about 50 picoseconds to 100 nanoseconds. In another aspect, laser pulse widths are in the range of from about 50 to 500 femtoseconds. In another aspect, laser pulse widths are in the range of from about 10 femtoseconds to about 500 picoseconds.

The number of laser pulses irradiating a target region can be in a range of from about 1 to about 2000. In one aspect, the number of laser pulses irradiating a target region can be from about 2 to about 1000. Further, the repetition rate or frequency of the pulses can be selected to be in a range of from about 10 Hz to about 10 μHz, or in a range of from about 1 kHz to about 1 MHz, or in a range from about 10 Hz to about 1 kHz. Moreover, the fluence of each laser pulse can be in a range of from about 1 kJ/m² to about 20 kJ/m², or in a range of from about 3 kJ/m² to about 8 kJ/m².

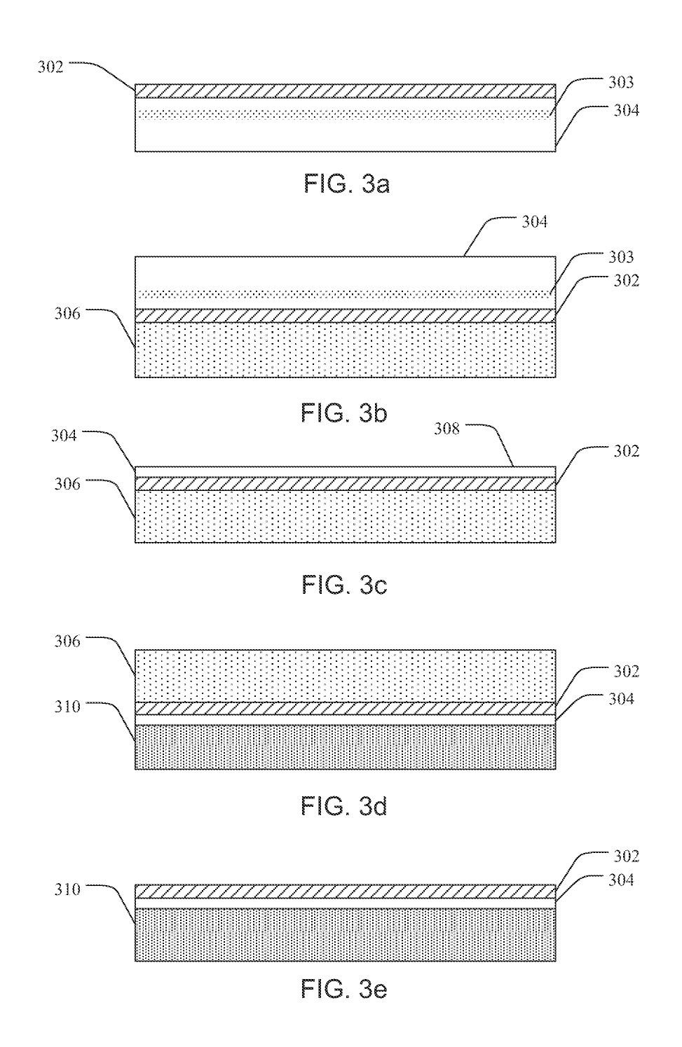

In another aspect, FIGS. 3a-e show various steps in the manufacture of a SOI device. As is shown in FIG. 3a, for example, device layer 302 can formed on the front side of a semiconductor layer 304. The device layer 302 can include any form of device layer that can be incorporated into a SOI device. A thin oxide layer 303 can be embedded within the semiconductor layer 304, either before or after the formation of the device layer 304. The thin oxide layer can be of any shape and thickness useful for the particular device design. In some aspects, however, the thin oxide layer can be from about 4000 angstroms to about 5000 angstroms thick. It is also noted that commercial SOI substrates can also be used, upon which the device layer is deposited.

Turning to FIG. 3b, a first substrate 306 (or front side substrate) can be bonded to the device layer 302. Note that in FIG. 3b, the device has been flipped or rotated 180°. The first substrate can include a variety of materials. Because in most aspects the first substrate 306 is a temporary substrate to be removed at a later processing step, the material can be chosen based on its usefulness as a temporary substrate.

Turning to FIG. 3c, the semiconductor layer 304 (FIG. 3b) is at least partially removed to form a processed surface 308 near the backside of the device layer 302. In one aspect, the semiconductor layer 304 can be removed at least to the thin oxide layer 303. In some aspects at least a portion of the thin oxide layer can remain, while in other aspects the thin oxide layer can be completely removed from the semiconductor layer. This material can be removed by any known method, such as, for example, laser splitting, polishing, thinning, etching, or a combination thereof. Thus, the resulting structure is comprised of the first substrate 306 coupled to the device layer 302. A portion of the semiconductor layer 304 can remain coupled to the device layer 302 opposite the first substrate 306. This portion of the semiconductor layer 304 can thus be a crystallographically high quality material, and in some aspects can be lightly doped, passivated and/or laser annealed at low temperatures (e.g. below about 350° C.). At this point, any necessary or beneficial backside processing can be performed on the device layer 302. In one specific aspect, processing the semiconductor layer on the backside can include implant and/or laser anneal conditions to reduce surface defects. It is also contemplated that backside circuitry can be formed at the backside surface of the device layer 302 prior to subsequent bonding.

Following thinning of the semiconductor layer 304, a second substrate 310 can be bonded to the semiconductor layer 304 at backside of the device layer 302, as is shown in FIG. 3d. Note that in FIG. 3d, the device has been rotated 180°. Any bonding technique can be utilized to bond the second substrate 310 to the semiconductor layer 304, as has been described.

Turning to FIG. 3e, in some aspects the first substrate 306 (FIG. 3d) can be removed from the device layer 302 following bonding of the second substrate 310. Thus, the resulting SOI structure shown in FIG. 3e includes an insulating substrate (second substrate 310) bonded to the semiconductor layer 304, which is bonded to the device layer 302. Because of the defect free formation of the device layer 302 on the semiconductor layer 304, and the subsequent low temperature processing of the device, the device layer 302 remains defect free or substantially defect free in the final SOI substrate or SOI device. It should be noted that the scope of the present disclosure includes the SOI substrate shown in FIG. 3e, as well as the intermediate structures produced during the formation of the SOI substrate.

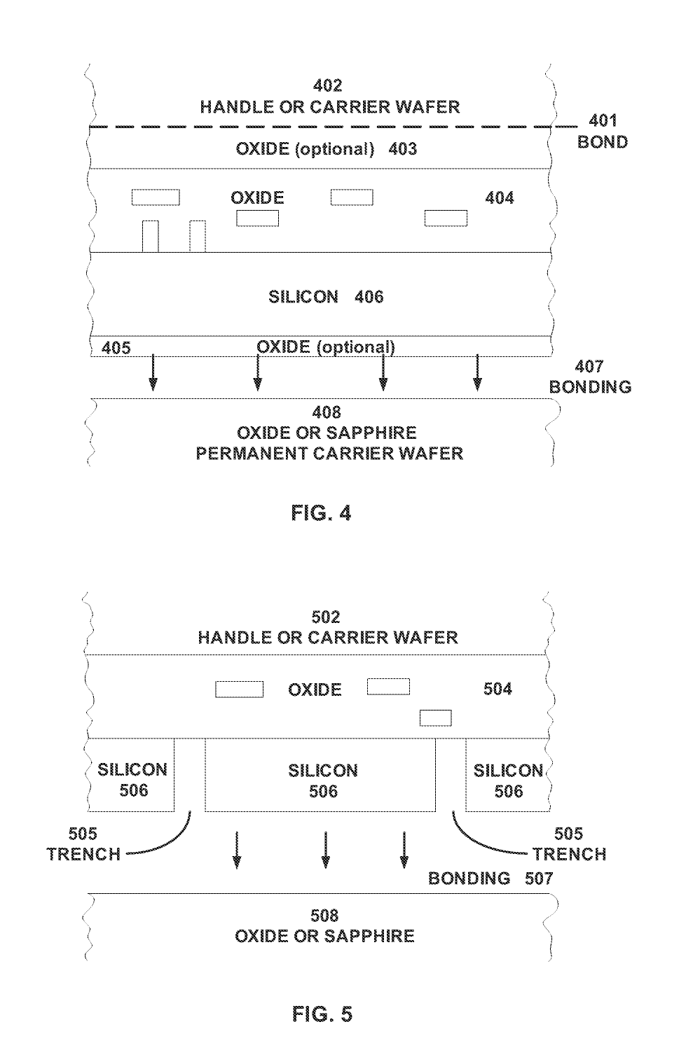

In one specific aspect, as is shown in FIG. 4, a structure having a thin or ultra-thin silicon device and circuit wafer with front side oxide and wiring 404, is provided. The structure is bonded to a permanent carrier wafer having a thick oxide, or in some cases a sapphire wafer 408. The front side bonding of the completed integrated circuit wafer 406 can be by an oxide-oxide bond, an oxide-silicon bond, an oxide-adhesive bond, or the like 401, to the first substrate or handle wafer 402. In one aspect, an oxide 403 can be utilized for bonding. The backside is thinned and an oxide can be deposited thereupon for use in an oxide-oxide bond, silicon-oxide bone, or for instance a silicon-sapphire bond 407 to the second substrate or sapphire substrate 408. Additionally, an oxide 405 can be deposited on the back of the device and circuit wafer, or in some aspects a substrate can be used such as is shown in FIG. 3. During these steps there is minimal damage to the device and circuit wafer that under goes only low temperature heat cycles.

It is also noted that other aspects involving a device layer on a temporary first substrate allows additional options in bonding. While the device layer is on the first substrate, the kerf area between die can be trench etched through the thin semiconductor layer (i.e. the device layer). If the layers are initially bonded under vacuum, then upon removal from the vacuum there can be a strong force adhering the layers together to avoid voids in bonding. As is shown in FIG. 5, for example, a thin or ultra-thin silicon device and circuit wafer with front side oxide and wiring 504 is bonded on to a second substrate with a thick oxide or a sapphire wafer 508. The front side bonding of the completed integrated circuit wafer 506 can be by an oxide-oxide bond, an oxide-silicon bond, or and oxide-adhesive bond to the temporary carrier or handle wafer 502. The backside is thinned, and an oxide can be deposited. Trenches 505 can be etched in the kerf area at the edges of the die, and then an oxide-oxide bond, silicon-oxide, or a silicon-sapphire bond can be made to the second substrate or sapphire substrate 508 under low temperatures in a vacuum. When the device is returned to atmospheric pressure the vacuum in the kerf areas will forced the wafers together, forming a void free bond. During these steps there is minimal damage to the device and circuit wafer that under goes only low temperature heat cycles.

As such, in one aspect at least one trench can be formed in the processed surface prior to bonding the second substrate to the processed surface. By bonding the second substrate to the processed surface under vacuum, negative pressure within the trench facilitates bonding of the processed surface to the second substrate.

It is to be understood that the above-described arrangements are only illustrative of the application of the principles of the present disclosure. Numerous modifications and alternative arrangements may be devised by those skilled in the art without departing from the spirit and scope of the present disclosure and the appended claims are intended to cover such modifications and arrangements. Thus, while the present disclosure has been described above with particularity and detail in connection with what is presently deemed to be the most practical embodiments of the disclosure, it will be apparent to those of ordinary skill in the art that numerous modifications, including, but not limited to, variations in size, materials, shape, form, function and manner of operation, assembly and use may be made without departing from the principles and concepts set forth herein.

What is claimed is:

1. A method for making a semiconductor-on-insulator device, comprising:
forming a device layer on a front side of a semiconductor layer;
bonding a first substrate to the front side of the device layer;
processing the semiconductor layer on a back side opposite the device layer to form a processed surface;
bonding a second substrate to the processed surface; and
removing the first substrate from the front side to expose the device layer.

2. The method of claim 1, wherein forming the device layer further includes forming optoelectronic circuitry at the front side of the semiconductor layer.

3. The method of claim 1, wherein forming the device layer further includes forming on the front side of the semiconductor layer a member selected from the group consisting of CMOS circuitry, imaging devices, RF circuitry, photovoltaic circuitry, or a combination thereof.

4. The method of claim 1, wherein the semiconductor layer includes a silicon material.

5. The method of claim 4, wherein the silicon material is a single crystal silicon wafer.

6. The method of claim 1, wherein processing the semiconductor layer on the back side further includes thinning the semiconductor layer from the back side to expose the device layer.

7. The method of claim 1, wherein processing the semiconductor layer on the back side further includes implant and/or laser anneal conditions to reduce surface defects.

8. The method of claim 1, wherein bonding the first substrate to the device layer further includes oxide-oxide bonding the first substrate to the device layer.

9. The method of claim 1, further comprising forming at least one trench in the processed surface prior to bonding the second substrate to the processed surface.

10. The method of claim 9, wherein the at least one trench is positioned in a kerf region of the processed surface.

11. The method of claim 10, wherein bonding the second substrate to the processed surface occurs under vacuum such that negative pressure within the trench facilitates bonding of the processed surface to the second substrate.

12. The method of claim 1, further comprising forming backside circuitry at the processed surface prior to bonding the second substrate to the processed surface.

13. The method of claim 1, wherein the bonding the second substrate to the processed surface further includes oxide-oxide bonding the second substrate to the processed surface.

14. The method of claim 1, wherein the second substrate is an insulating substrate.

15. The method of claim 14, wherein the second substrate is comprised of sapphire.

16. The method of claim 14, wherein the second substrate is an oxide material.

17. The method of claim 1, wherein the semiconductor-on-insulator device is not heated above a temperature of 450° C. following processing of the back side to form the processed surface.

18. The method of claim 1, wherein the device layer of the semiconductor-on-insulator device is substantially defect free.

19. A semiconductor-on-insulator device made according to claim 1.

20. A semiconductor-on-insulator device, comprising:
a semiconductor layer having a device layer on a front side and a CMP processed surface opposite the front side;
a first substrate oxide bonded to the device layer of the semiconductor layer; and
a second substrate oxide bonded to the processed surface of the semiconductor layer.

21. The device of claim 20, wherein the device layer is substantially defect free.

22. The device of claim 20, wherein the device layer includes optoelectronic circuitry.

23. The device of claim 20, wherein the device layer includes a member selected from the group consisting of CMOS circuitry, RF circuitry, photovoltaic circuitry, or a combination thereof.

24. The device of claim 20, wherein the semiconductor layer includes a silicon material.

25. The device of claim 24, wherein the silicon material is a single crystal silicon wafer.

26. The device of claim 20, further including at least one trench formed in the processed layer and positioned to apply a negative pressure between the semiconductor layer and the second substrate.

27. The device of claim 20, wherein the second substrate is an insulating substrate.

28. The device of claim 20, wherein the second substrate is a sapphire layer.

29. The device of claim 20, wherein the second substrate is a permanent substrate.
